(19) United States
(12) Patent Application Publication
(10) Pub. No.: US 2013/0265034 A1
(43) Pub. Date: Oct. 10, 2013

(54) METHOD AND APPARATUS OF DYNAMIC FAST SPECTRAL SURVEY

(71) Applicants: RAUL SALVI, BOCA RATON, FL (US); THOMAS R. HARRINGTON, MARGATE, FL (US); SPYROS KYPEROUNTAS, WESTON, FL (US)

(72) Inventors: RAUL SALVI, BOCA RATON, FL (US); THOMAS R. HARRINGTON, MARGATE, FL (US); SPYROS KYPEROUNTAS, WESTON, FL (US)

(73) Assignee: MOTOROLA SOLUTIONS, INC., Schaumburg, IL (US)

(21) Appl. No.: 13/438,921

(22) Filed: Apr. 4, 2012

(51) Int. Cl. G01R 23/16

(52) U.S. Cl. 324/76.12

(57) ABSTRACT

A method and apparatus for multi-resolution multi-bandwidth spectral signal estimation is provided herein. During operation, a plurality of detectors is provided to determine if an input signal is above a predetermined threshold. The input signal comprises a first frequency range having a first bandwidth. If it is determined that the input signal of the first bandwidth is above a first predetermined threshold, then the same plurality of detectors are used to further analyze sub-bands of the first frequency range, each sub-band having a second bandwidth less than the first bandwidth. The further analysis determines if an input signal to a detector is above a second predetermined threshold.

### FIELD OF THE INVENTION

The present invention generally relates to signal detection, and more particularly to fast spectral survey to determine signal presence.

### BACKGROUND OF THE INVENTION

In a cognitive radio system of the type considered for use by IEEE 802.22, a cognitive secondary radio system will utilize spectrum assigned to a primary system using an opportunistic approach. With this approach, the secondary radio system will share the spectrum with primary incumbents as well as those operating under authorization on a secondary basis. Under these conditions, it is imperative that any user in the cognitive radio system not interfere with primary users.

Having spectrum awareness is an essential tool for agile cognitive radios where they may access unlicensed spectrum opportunistically, when other primary or secondary systems are not using it. For a robust and efficient wide-band spectral usage, especially when channel's instantaneous as well as long run occupancy varies over time, fast and reliable sensing of vast spectrum that will result in an accurate time-varying statistical channel characterization is a must. Therefore, a need exists for a method and apparatus for a dynamic fast spectral survey to determine signal presence.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is block diagram spectral-sensing circuitry.

FIG. 2 illustrates the operation of the circuitry of FIG. 1 on various frequency bands.

FIG. 3 illustrates the operation of the circuitry of FIG. 1 on various frequency bands.

FIG. 4 is a flow chart showing operation of the spectral-sensing circuitry of FIG. 1.

FIG. 5 is a flow chart showing operation of a detector of FIG. 1.

FIG. 6 illustrates a spectral occupancy graph.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required.

### DETAILED DESCRIPTION

In order to address the above-mentioned need, a method and apparatus for a multi-resolution, multi-bandwidth spectral survey to determine signal presence is provided herein. During operation, a plurality of detectors is provided to determine if an input signal is above a predetermined threshold. The input signal comprises a first frequency range having a first bandwidth. If it is determined that the input signal of the first bandwidth is above a first predetermined threshold, then the same plurality of detectors are used to further analyze sub-bands of the first frequency range, each sub-band having a second bandwidth less than the first bandwidth. The further analysis determines if an input signal to a detector is above a second predetermined threshold.

This above-described method and apparatus allows for fast and reliable low to high resolution spectral occupancy updates. Furthermore, the ability of the above method and apparatus to adaptively change the band being analyzed, the frequency resolution, and the threshold or amplitude resolution, lends itself for fast detection and classification of signals in a large amount of spectrum.

The following description describes a receiver used to rapidly detect energy throughout a vast spectrum to determine channel occupancy. The receiver comprises a down-converting frequency mixer with an agile local oscillator (LO synthesizer) frequency source, a channel filter followed by a vector-magnitude level detector with its threshold set above the channel noise floor for acceptable falsing-rate statistics whose output signals occupancy, a LO synthesizer dwell timer controlling the LO synthesizer source's frequency such that the LO synthesizer dwells for the channel filter's minimum required time to allow the detector to trip if energy stronger than noise exists (i.e. minimum time is the filter's group delay), a channelization scheme to either rapidly step through frequency spectrum sequentially (sequential processing) or rapidly sweep through frequency spectrum simultaneously (parallel processing).

A plurality of level detectors is combined in order to trade-off level resolution versus frequency resolution and detection speed. A multiplexor can be switched such that one channel filter is connected to all level detectors with the level detector thresholds scaled for multi-bit level detection (high resolution). Furthermore, the operation allows for one or fewer level detectors be distributed in different bands for multiband low resolution detection.

The method and apparatus provide a parallel processing signal acquisition system that utilizes a multi-filter (Multi Bandwidth), multi-detector & multi-resolution time varying approach. The system can acquire large sections of bandwidth at low resolution in several orders of magnitude less time and then quickly reconfigure to a more traditional higher resolution signal acquisition and demodulation system.

The method and apparatus enables a means to rapidly acquire time dependent information and classification of a large frequency band for further analysis, classification, tracking, utilization, occupancy and/or demodulation. Detectors and filters can be quickly re-configured for trading off low resolution/low latency for high resolution/high latency. These detectors and filters can process distinct spectrums and signals concurrently and independently.

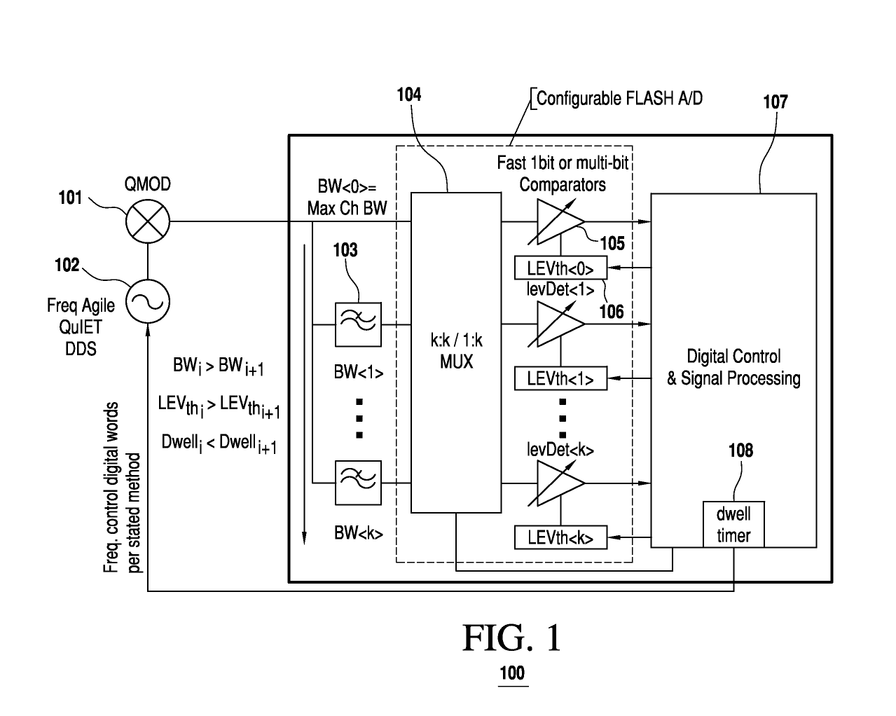

Turning now to the drawings, wherein like numerals designate like components, FIG. 1 is a block diagram of an apparatus 100 used for a multi-resolution, multi-bandwidth spectral survey to determine signal presence. As shown, apparatus 100 comprises direct digital synthesizer/frequency source 102 coupled to modulator/mixer 101. FIG. 1 shows a down-converting frequency mixer 101 with an agile local oscillator (LO synthesizer) frequency source 102. Mixer 101 outputs a signal based on LO 102 tuning. At least one channel filter 103 is provided for filtering the signal. A plurality of signal detectors 105 are provided coupled to channel filters 103 through multiplexer 104. Signal detectors 105 have a threshold 106 set above a channel noise floor, and detecting occupancy of a portion of the signal. LO synthesizer dwell timer 108 is provided for controlling the LO synthesizer source frequency such that the LO 102 dwells for a time required by the channel filter to allow the plurality of detectors 105 to detect a signal energy stronger than the channel noise floor. Logic circuitry 107 is provided for instructing signal detectors 105 the frequency mixer 101, the local oscillator 102, and the channel filters 103 to step through frequency spectrum sequentially or simultaneously.

In combination, LO 102 and modulator 101 are capable of providing an output from modulator 101 having a particular bandwidth and frequency range. Low-pass or band-pass filters 103 (only one labeled) are provided to filter a particular frequency band output from modulator 101. Multiplexer 104 combines the outputs of the filters 103. The combined output is provided to a plurality of detectors 105 (only one labeled).

In one embodiment detectors 105 comprise simple one-bit detectors that serve to simply indicate (via a 0 or a 1) if an input is above a particular threshold level (LEVth). The threshold level 106 is output to/from logic circuitry 107. Logic circuitry 107 comprises a digital signal processor (DSP), general purpose microprocessor, a programmable logic device, or application specific integrated circuit (ASIC) and is utilized to access and control apparatus 100. As shown, logic circuitry 107 serves as dwell timer 108 that controls the timing of frequency sweeps and the particular frequency bands output by modulator 101, as well to control and change bandwidths output from multiplexer 104 to any particular detector 105. Additionally logic circuitry 107 modifies thresholds utilized by detectors 105.

During operation LO 102 is tuned to output a first bandwidth within a first frequency range from modulator 101. A first threshold level 106 (LEVth<0>) for a first detector 105 set to an acceptable level above a receive noise floor. LO 102 dwell timer set to the minimum time required to trip a detection by detector 105 (this criteria speeds up the detection process since we are only interested in a binary result as to whether energy is present and not interested in waiting the extra time required to allow the energy to grow to its full magnitude). The dwell time is inversely proportional to channel bandwidth, i.e. smaller bandwidth longer dwell time and vice versa.

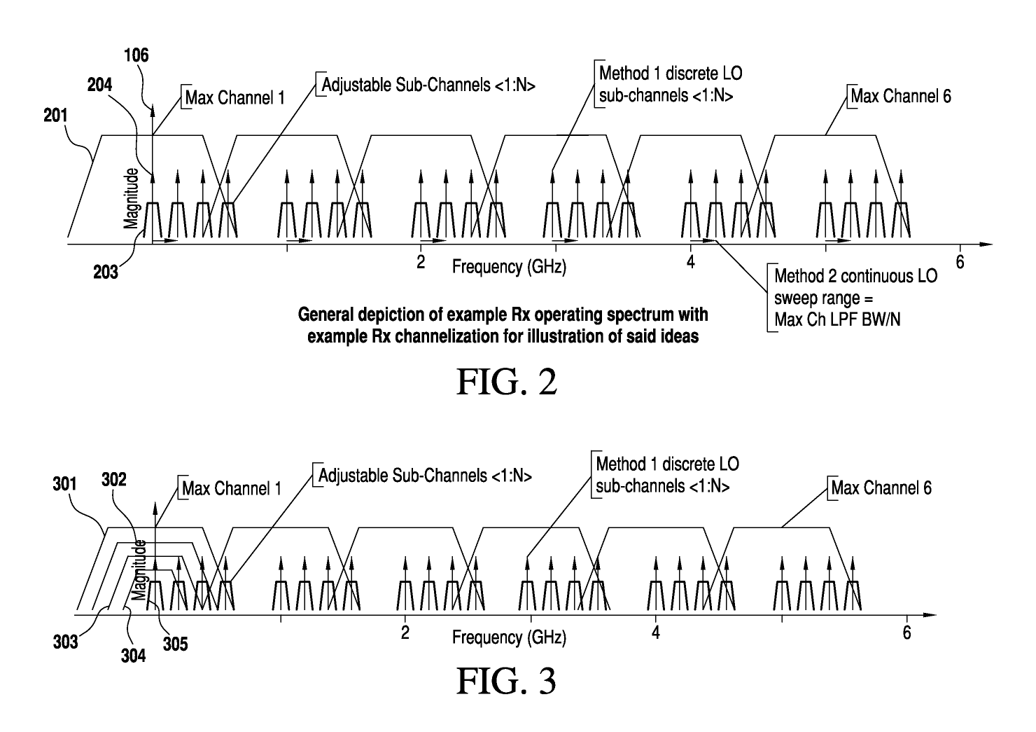

The first bandwidth, within the first frequency range (referred to from here on as a first wideband signal) enters a single first detector 105. If the input signal amplitude to the single first detector 105 is above a predetermined threshold, multiple detectors 105 (including the single first detector 105) are utilized to further analyze the first wideband signal. Logic circuitry 107 continuously monitors the outputs of all detectors 105. More specifically, if the first single detector detects a signal within the first wideband signal, logic circuitry 107 then instructs multiple detectors 105 to analyze narrowband portions of the first wideband signal. This is accomplished by inputting a narrowband portion of the first wideband signal into each detector 105, covering the frequency range. This is illustrated in FIG. 2.

As shown in FIG. 2, the first wideband signal 201 will be input into a single first detector 105. The first single detector 105 determines if the first wideband signal is above threshold 106. If so, then multiple detectors 105 (including the first detector used originally) are used to analyze narrowband portions 203 of the first wideband signal 201. Thus, the input to first detector 105 will be narrowband portion 203 of the first wideband signal 201. Each narrowband portion 203 has a bandwidth that is much less than the first wideband signal 201. Additionally, second threshold levels 204 are utilized for detectors 105 analyzing the narrowband portions 203.

The above process can be run in parallel for multiple wideband signals by simultaneously passing a wideband signal to one of the plurality of detectors 105 and then narrowing the bandwidth until the complete bandwidth of interest has been analyzed. For each wideband signal, LO 102 and modulator 101 can be stepped through N sub-channels using threshold levels set above a receive noise floor and dwell timer set to corresponding minimum time for detection. As energy is detected logic circuitry 107 arranges the resultant bits to create a time-frequency spectrogram bitmap (this will be described below).

Although the process of FIG. 2 was described having two frequency bandwidths (a wideband and a narrowband), as shown in FIG. 3, multiple bandwidths may be fed into the same detector 105. Thus, a first wideband signal 301 will be input into a single first detector 105. The single, first detector 105 determines if the first wideband signal is above a first threshold. If so, then detector 105 may be used to analyze second signal 303 having a bandwidth less than wideband signal 301. This process repeats for signals 304 and 305. This process happens concurrently with adjacent wideband signals 2, 3, 4, 5, 6, etc.

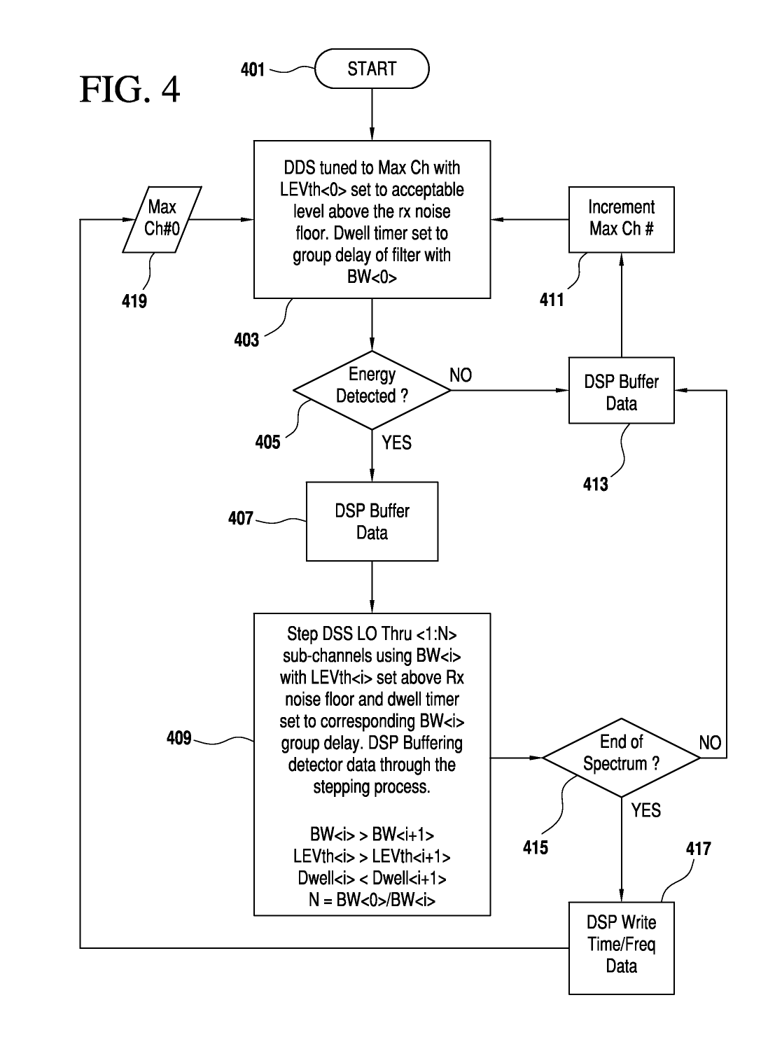

FIG. 4 is a flowchart showing operation of apparatus 100. The logic flow begins at step 401. At step 403 logic circuitry 107 tunes LO 102 to a maximum channel bandwidth and sets detector threshold level 106 to a first value for scanning a first channel. At step 403 logic circuitry 107 also sets a dwell timer for an appropriate delay based on the maximum channel bandwidth. At step 405 logic circuitry 107 determines if energy has been detected on the first channel (CH#0) having the maximum bandwidth from any detector 105. If not, the logic flow continues to step 413 where data is stored and the first channel is incremented to a second channel to be scanned (step 411).

However, if at step 405 logic circuitry 107 detects energy on a given channel, the data is stored (step 407), and that channel is scanned at a narrower bandwidth (step 409). More particularly, LO 102 and modulator 101 are set to pass N narrowband channels within the previous wideband channel. The threshold detector level 106 is also adjusted accordingly, and detectors 105 determine if any narrowband channels have energy above a threshold. At step 415 logic circuitry 107 determines if all narrowband channels have been scanned. If so, the data is stored (step 417) and the logic flow continues to step 419 where the necessary parameters are set again to scan the first channel (CH#0). If, however, at step 415 it is determined that all narrowband channels have not been scanned, then the logic flow returns to step 413.

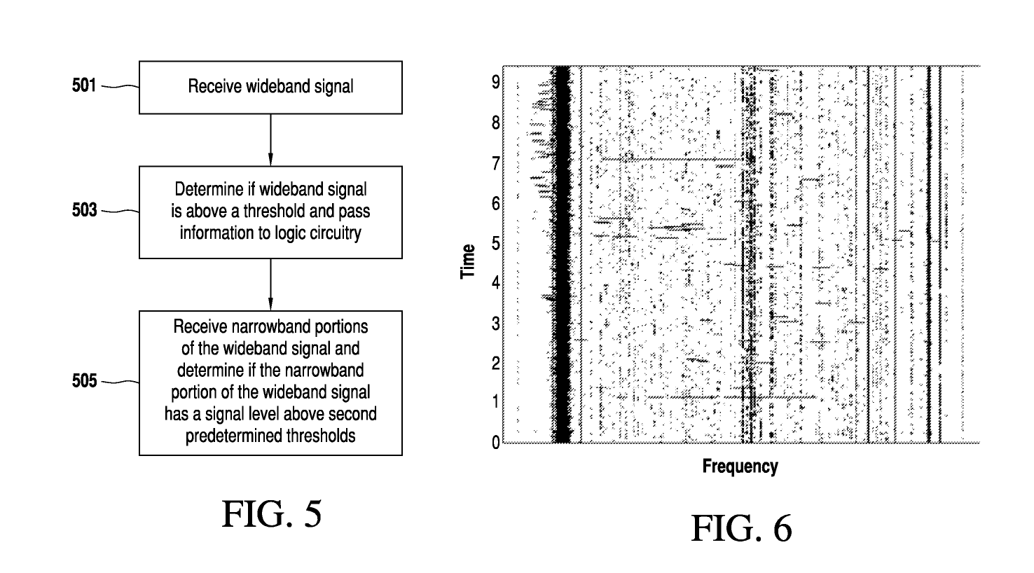

FIG. 5 is a flow chart showing operation of a single detector 105. The logic flow begins at step 501 where a first detector 105 receives a wideband signal. The first detector then determines if the wideband signal level is above a first predetermined threshold, and passes this information on to logic circuitry 107 (step 503). At a later time period, first detector 105 along with other detectors receive narrowband portions of the wideband signal and determines if the narrowband portion of the wideband signal has a signal level above second predetermined thresholds. This information is passed to logic circuitry 107 (step 505).

The process described in FIG. 5 may take place in parallel using other detectors. More particularly, in parallel with receiving the wideband signal at the first detector, a second wideband signal may be received at a second detector at a same time the wideband signal is received at the first detector. The second detector will determine if the second wideband signal level is above the first predetermined threshold (or a differing threshold). Narrowband portions of the second wideband signal will then be received at the plurality of detectors, including the second detector, and a determination will be made by the plurality of detectors if the narrowband portions of the second wideband signal have signal levels above the second predetermined thresholds.

It should be noted that all of the detectors described in FIG. 5 may be one-bit detectors. Additionally all thresholds are based on a bandwidth of the signal input into the detector. In an alternate embodiment LO 102 and modulator 101 may be designed to simply pass through the received wideband signal to filters 103. In this embodiment at least one filter 103 would comprise a large bandwidth filter, allowing the whole signal of interest to pass through.

Arranging Resultant Bits into a Time-Frequency Spectrogram Bitmap

As a first step, spectral occupancy information is needed. This is provided as described above. More particularly, the spectral updates come in the form of binary occupancy data for the different frequencies (1 bit data representation), which implies that the energy detection is already performed in the sensing process. These data are passed from detectors 105 to DSP 107 where they can be combined to describe the occupancy and classification of a channelized spectrum (uniform or variable BWs per channel) as in FIG. 6.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

Those skilled in the art will further recognize that references to specific implementation embodiments such as “circuitry” may equally be accomplished via either on general purpose computing apparatus (e.g., CPU) or specialized processing apparatus (e.g., DSP) executing software instructions stored in non-transitory computer-readable memory. It will also be understood that the terms and expressions used herein have the ordinary technical meaning as is accorded to such terms and expressions by persons skilled in the technical field as set forth above except where different specific meanings have otherwise been set forth herein.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment.

Thus the following claims are hereby incorporated into the Detailed Description, with each claim standing on its own as a separately claimed subject matter.

What is claimed is:

1. A method for multi-resolution spectral signal detection, the method comprising the steps of:
receiving a wideband signal at a first detector;
determining, by the first detector, if the wideband signal level is above a first predetermined threshold;
receiving narrowband portions of the wideband signal at a plurality of detectors, including the first detector;
determining by the plurality of detectors, if the narrowband portions of the wideband signal have signal levels above second predetermined thresholds.

2. The method of claim 1 further comprising the steps of:
in parallel with receiving the wideband signal at the first detector, receiving a second wideband signal at a second detector at a same time the wideband signal is received at the first detector;
determining, by the second detector, if the second wideband signal level is above the first predetermined threshold;
receiving narrowband portions of the second wideband signal at the plurality of detectors, including the second detector;
determining by the plurality of detectors, if the narrowband portions of the second wideband signal have signal levels above the second predetermined thresholds.

3. The method of claim 2 wherein the first and the second detectors comprise one-bit detectors.

4. The method of claim 3 wherein the first predetermined threshold are based on a bandwidth of the wideband signal.

5. The method of claim 1 further comprising the step of creating a bitmap of frequency occupancy over time.

6. An apparatus for detecting energy to determine channel occupancy, the apparatus comprising:
a down-converting frequency mixer with an agile local oscillator (LO synthesizer) frequency source outputting a signal;
a channel filter filtering the signal;
a plurality of a signal detectors coupled to the channel filter, the signal detectors having a threshold set above a channel noise floor, and detecting occupancy of a portion of the signal;
a LO synthesizer dwell timer controlling the LO synthesizer source frequency such that the LO synthesizer dwells for the a time required by the channel filter to allow the plurality of detectors detect a signal energy stronger than the channel noise floor; and
logic circuitry instructing the signal detectors, the frequency mixer, the local oscillator, and the channel filter to step through frequency spectrum sequentially or simultaneously.

7. The apparatus of claim 6 wherein the signal detectors comprise one-bit detectors.

8. The apparatus of claim 7 wherein the threshold are based on a bandwidth of the portion of the signal.

9. The apparatus of claim 6 wherein the logic circuitry creates a bitmap of frequency occupancy over time.

10. A method comprising the steps of:
receiving a signal;
filtering the signal;
detecting occupancy of a portion of the signal with signal detectors by determining if an energy level is above a threshold;
instructing the signal detectors, the frequency mixer, the local oscillator, and the channel filter to step through frequency spectrum sequentially or simultaneously.

11. The method of claim 10 wherein the signal detectors comprise one-bit detectors.

12. The method of claim 10 wherein the thresholds are based on a bandwidth of the signal input into the detector.

13. The method of claim 10 further comprising the step of creating a bitmap of frequency occupancy over time.
